(19) United States
(12) Patent Application Publication
(10) Pub. No.: US 2016/0086908 A1
(43) Pub. Date: Mar. 24, 2016

(54) ADHESIVE AGENT COMPOSITION, ADHESIVE SHEET, AND METHOD FOR MANUFACTURING SEMICONDUCTOR DEVICE

(71) Applicant: LINTEC CORPORATION, Tokyo (JP)

(72) Inventors: Sayaka Tsuchiyama, Tokyo (JP); Naoya Saiki, Tokyo (JP); Yuichiro Azuma, Tokyo (JP); Hideaki Suzuki, Tokyo (JP)

(73) Assignee: LINTEC CORPORATION, Tokyo (JP)

(21) Appl. No.: 14/888,509

(22) PCT Filed: May 27, 2014
(86) PCT No.: PCT/JP2014/063979

§ 371 Date: Nov. 2, 2015

(30) Foreign Application Priority Data
May 28, 2013 (JP) 2013-111974
Jun. 17, 2013 (JP) 2013-126935

(51) Int. Cl. H01L 23/00; C09J 133/10; H01L 25/00; H01L 21/78; H01L 21/683

(52) U.S. Cl. CPC H01L 24/29; H01L 21/78; H01L 21/6835; H01L 24/83; H01L 25/50; H01L 24/27; H01L 24/94; C09J 133/10; H01L 2221/68377; H01L 2221/68327; H01L 2224/8385; H01L 2924/05442; H01L 2924/0635; H01L 2221/68381; H01L 2221/6834; H01L 2224/27003; H01L 2224/27436; H01L 2224/2929; H01L 2224/32145; H01L 2224/32245; C08K 9/04

(57) ABSTRACT

An adhesive composition includes an acrylic polymer (A), a heat curable resin (B) having a reactive double bond group, and a filler (C) having a reactive double bond group on a surface thereof. The acrylic polymer (A) has a weight average molecular weight of 500,000 or more, and the heat curable resin (B) comprises an epoxy resin and a heat curing agent, in which at least one of the epoxy resin and the heat curing agent has the reactive double bond group.

### TECHNICAL FIELD

The present invention relates to an adhesive composition particularly suitable to be used during the step of adhering (die bonding) a semiconductor chip to an organic circuit board or a lead frame or to other semiconductor chip, and also relates to an adhesive sheet having the adhesive layer comprising_said adhesive composition, and further relates to a production method of the semiconductor device using said adhesive sheet.

### BACKGROUND ART

A semiconductor wafer of silicon and gallium arsenic or so is produced in a large diameter, and this wafer is cut and separated (dicing) into small pieces of the element (the semiconductor chip), then moves on to the mounting step which is the subsequent step. At this time, the semiconductor wafer is adhered on the adhesive sheet in advance and the steps of dicing, washing, drying, expanding, and pickup are carried out respectively, then it moves on to the bonding step which is the subsequent step.

Among these steps, in order to simplify the processes of the pickup step and the bonding step, various dicing-die bonding adhesive sheets, which have both of wafer fixing function and die adhesive function, are proposed (refer to the patent article 1). The adhesive sheet disclosed in the patent article 1 enables the so-called direct die bonding, and allows omitting coating step of die adhering adhesive agent. This adhesive agent includes acrylic polymer, epoxy resin having reactive double bond group, and heat curing agent; and if needed, filler such as silica may be included.

The property required against the recent semiconductor device is extremely severe. For example, in regards with the connection of the electrical parts, the surface mounting method (reflow) wherein the entire package is exposed to a high temperature which is higher than melting point of soldering is being carried out. Further, recently, due to the transition to the soldering which does not include lead, mounting temperature has increased to 260° C. or so. Therefore, the stress generated inside the semiconductor package during the mounting has become larger than before, hence the chances of causing problems such as peel or package crack at the adhesive boundary have increased. Thus, in said patent article 1, as for epoxy resin, the epoxy resin having reactive double bond group is used to improve the compatibility between the acrylic polymer and the epoxy resin, thereby adhesive reliability is improved.

Also, for the high density mounting, the package structure in which the chips are multiply stacked is proposed. In this package structure, not only adhesion between the circuit board and the chip, but also adhesion between the chip and the chip is necessary. In the multistacked package, the chip is stacked on the chip via the adhesive layer and after curing the adhesive layer, the wire bonding is carried out, then further the stacking of the chip, curing of the adhesive layer, the wire bonding are carried out one after another, thereby the chips are stacked.

The following processes are examined in a production method of such semiconductor device of the package structure in which chips are multistacked. First, stacking and wire bonding are carried out while the adhesive layer is uncured or semi-cured, and all the chips are stacked. Subsequently, the adhesive layers are collectively full-cured taking an advantage of a mold sealing process, in which the package structure is exposed to high temperature for a long time. However, when applying such production method, the adhesive layer is not cured or semi-cured during the wire bonding. Therefore, the chip vibrates or displaced during the wire bonding; the position of the wire may be inaccurate or the wire bonding may not be carried out. In order to solve such problem, when using the above mentioned production method, even if it is before cured, a relatively hard adhesive agent will be used. As for the means to make the adhesive agent of before curing harder, it is thought to blend a relatively large amount of the filler in the adhesive agent.

### PRIOR ART DOCUMENT

[Patent Article 1] JP Patent Application Laid Open No. 2008-133330

### DISCLOSURE OF INVENTION

### Problem to be Solved by the Invention

However, it is not necessarily easy to uniformly mix the filler in the adhesive agent. If dispersibility of the filler in the adhesive agent is bad, appearance of the particle diameter becomes large due to aggregation between the fillers, thereby thickness accuracy of the adhesive layer may be lowered, or it may be the cause to lower lamination property and the adhesiveness between the semiconductor wafers. Particularly, if the blending amount of the filler increases, the above mentioned problem becomes prominent. Also, if the filler is blended to the adhesive agent in a large amount, the blending amount of the curable component (the epoxy resin or so) decreases relatively, thereby the reliability of the adhesive layer after the curing may be lowered.

Further, even when the process to carry out simultaneous curing of the adhesive layer as mentioned in the above is used, high temperature of 150° C. or higher is necessary during the wire bonding; thus in some case the adhesive layer was partially cured. In case of such undesirable curing, the pressure is not applied, hence when the adhesive layer is cured; the adhesive force is simply lost which leads to lowering of the adhesive strength. When the adhesive layer is partially cured, the following property to the rough surface is lowered particularly, and the adhesiveness against the circuit board surface or die pad having relatively large roughness declines significantly.

Therefore, the object of the present invention is to provide an adhesive composition, and an adhesive sheet having an adhesive layer comprising said adhesive composition, and production method of a semiconductor device using said adhesive sheet; capable of uniformly mixing the filler in the adhesive layer, capable of stably carrying out wire bonding before the simultaneous curing even when the process of carrying out simultaneous curing of the adhesive layer is applied when producing the multistacked package, and exhibiting an excellent adhesive strength after the curing; further particularly capable of accomplishing high packaging reliability in the semiconductor device.

The present invention which solves the above mentioned problems include the following points.

(1) An adhesive composition including an acrylic polymer (A), a heat curable resin (B) having a reactive double bond group, and a filler (C) having a reactive double bond group on a surface thereof, in which the acrylic polymer (A) has a weight average molecular weight of 500,000 or more, and the heat curable resin (B) comprising an epoxy resin and a heat curing agent, in which at least one of the epoxy resin and the heat curing agent has the reactive double bond group.
(2) An adhesive composition including an acrylic polymer (A), a heat curable resin (B) having a reactive double bond group, and a filler (C) having a reactive double bond group on a surface thereof, in which the filler (C) has an average particle diameter of 0.01 to 0.2 μm, and the heat curable resin (B) comprising an epoxy resin and a heat curing agent, in which at least one of the epoxy resin and the heat curing agent has the reactive double bond group.
(3) The adhesive composition as set forth in (1) or (2), in which the filler (C) is silica having the reactive double bond group on a surface thereof.
(4) The adhesive composition as set forth in any one of (1) to (3), in which a content ratio of the acrylic polymer (A) is 50 to 90 wt % with respect to a whole weight of the adhesive composition.
(5) The adhesive composition as set forth in any one of (1) to (4), in which the acrylic polymer (A) has a hydroxyl group.
(6) A single layer adhesive film comprising an adhesive composition as set forth in any one of (1) to (5).
(7) A single layer adhesive film comprising the adhesive composition as set forth in (2), in which shear strength thereof after curing at 250° C. is 60N/5 mm□ or more.
(8) An adhesive sheet, in which an adhesive layer, comprising the adhesive composition as set forth in any one of (1) to (5), is formed on a support.
(9) An adhesive sheet, in which an adhesive layer, comprising the adhesive composition as set forth in (2), is formed on a support, and shear strength of the adhesive layer after curing at 250° C. is 60N/5 mm□ or more.
(10) The adhesive sheet as set forth in (8) or (9), wherein the support is a resin film.
(11) The adhesive sheet as set forth in (8) or (9), wherein the support is a sticky sheet.
(12) A production method of a semiconductor device including the steps of: laminating the adhesive layer of the adhesive sheet as set forth in any one of (8) to (11) on a semiconductor wafer, dicing the semiconductor wafer and the adhesive layer, thereby obtaining a semiconductor chip, releasing the semiconductor chip from the support while the adhesive layer is transferred to the semiconductor chip, and adhering the semiconductor chip on a die pad or on other semiconductor chip via said adhesive layer.
(13) A production method of a semiconductor device including the steps of: separating a semiconductor wafer into individual semiconductor chips by forming a groove from the surface of the semiconductor wafer along an outline of a shape of the separating semiconductor chip, laminating a protective sheet on the surface of the semiconductor wafer, and then performing a thinning treatment from the rear surface until reached to the groove, laminating the adhesive layer of the adhesive sheet as set forth in any one of (8) to (11) on the semiconductor chip, releasing the semiconductor chip from the support while the adhesive layer is transferred to the semiconductor chip, and adhering the semiconductor chip on a die pad or on other semiconductor chip via said adhesive layer.

According to the first invention of the present invention, by using the acrylic polymer of a predetermined weight average molecular weight, the heat curable resin having the reactive double bond group, and the filler having the reactive double bond group on a surface thereof; and according to the second invention of the present invention, by using the acrylic polymer, the heat curable resin having the reactive double bond group, and the filler having the reactive double bond group on a surface thereof and a predetermined average particle diameter, compatibility of the acrylic polymer, heat curable resin and filler in the adhesive composition improves, and also dispersibility of the filler in the adhesive composition improves. In addition, a three dimensional network is formed in the adhesive composition by an additional polymerization of the reactive double bond groups. As a result, a semiconductor chip can be adhered to other semiconductor chip or to circuit board with superior adhering strength, and a semiconductor device showing high package reliability can be obtained even under a severe condition. Further, the wire bonding can be stably performed to the adhesive layers, due to uncured or semi-cured adhesive layers showing high hardness to certain degree.

### MODES FOR CARRYING OUT THE INVENTION

Hereinafter, the present invention relating to the adhesive composition, the adhesive sheet, and the production method of the semiconductor device using the adhesive sheet will be described in detail.

### (The Adhesive Composition)

The adhesive composition of the present invention includes an acrylic polymer (A) (hereinafter it may be referred as “(A) component” as same as other components), a heat curable resin (B), and a filler (C) as essential components; and, in order to improve the various physical properties, other components may be blended depending on the needs. Hereinafter, these components will be explained in detail.

(A) Acrylic Polymer

Weight average molecular weight (Mw) of acrylic polymer (A) of the first invention is 500,000 or more, preferably 500,000 to 2,000,000, more preferably 500,000 to 1,500,000, and the most preferably 500,000 to 800,000. If the weight average molecular weight of acrylic polymer (A) becomes less than 500,000, cohesion of adhesive layers reduces and package reliability of a semiconductor device produced with the adhesive layers degrades. While if the weight average molecular weight of acrylic polymer (A) becomes excessively high, lamination property to adherend, such as semiconductor wafer, chip, circuit board, and so on, may be lowered, causing voids or defective transfers in some cases.

Weight average molecular weight (Mw) of acrylic polymer (A) of the second invention is not particularly limited; however, it is preferably 500,000 or more, more preferably 500,000 to 2,000,000, further preferably 500,000 to 1,500,000, and the most preferably 500,000 to 800,000. If the weight average molecular weight of acrylic polymer (A) becomes less than 500,000, cohesion of adhesive layers may reduce. According to the second invention, however, by using the filler described below having predetermined average particle diameter, adhesiveness between the adherend and the adhesive layer improves, and thus, package reliability of the semiconductor device becomes superior. While if the weight average molecular weight of acrylic polymer (A) becomes excessively high, lamination property to adherend may be lowered, causing voids or defective transfers in some cases.

Further, a molecular weight distribution (Mw/Mn, Mn is a number average molecular weight) of acrylic polymer (A) is preferably 1 to 5 and more preferably 1 to 3. By setting the molecular weight distribution of acrylic polymer (A) within the above range, an effect of improving package reliability of the invention becomes higher. Note that the weight average molecular weight (Mw), the number average molecular weight (Mn), and the molecular weight distribution (Mw/Mn) of acrylic polymer (A) are polystyrene corresponding values measured under the measuring conditions below by gel/permeation chromatography (GPC) method.

The glass transition temperature (Tg) of acrylic polymer (A) is preferably within a range of −20 to 50° C., more preferably −10 to 40° C., and further preferably 0 to 30° C. In case when Tg of acrylic polymer (A) is within the above arrange, package reliability tends to increase. The following methods can be exemplified as adjusting methods of the glass transition temperature of acrylic polymer (A). For instance, methods to increase the glass transition temperature, when using the below alkyl(meth)acrylate having a carbon number of 1 to 18 as a monomer constituting acrylic polymer (A), may include: a method of selecting alkyl(meth)acrylate, in which the alkyl group has a small carbon number, and a method of enlarging a content ratio of alkyl(meth)acrylate, in which the alkyl group has a small carbon number. The glass transition temperature of acrylic polymer (A) is obtained by FOX equation.

The monomer constituting acrylic polymer (A) of the invention includes at least (meth)acrylate monomer and its derivatives. Examples of (meth)acrylate monomer and its derivatives include alkyl(meth)acrylate having 1 to 18 carbon atoms of alkyl group, (meth)acrylate having cyclic skeleton, (meth)acrylate containing hydroxyl group, (meth)acrylate containing glycidyl group, (meth)acrylate containing amino group, and (meth)acrylate containing carboxyl group.

Examples of alkyl(meth)acrylate having the carbon number of 1 to 18 include methyl(meth)acrylate, ethyl(meth)acrylate, propyl(meth)acrylate, butyl(meth)acrylate, pentyl(meth)acrylate, hexyl(meth)acrylate, heptyl(meth)acrylate, octyl(meth)acrylate, 2-ethylhexy(meth)acrylate, nonyl(meth)acrylate, decyl(meth)acrylate, lauryl(meth)acrylate, tetradecyl(meth)acrylate, octadecyl(meth)acrylate or so. Examples of (meth)acrylate having cyclic skeleton include cycloalkyl(meth)acrylate, benzyl(meth)acrylate, isobornyl(meth)acrylate, dicyclopentanyl(meth)acrylate, dicyclopentenyl(meth)acrylate, dicyclopentenyloxyethyl(meth)acrylate, imide(meth)acrylate or so. Examples of (meth)acrylate containing hydroxyl group include 2-hydroxyethyl(meth)acrylate, 2-hydroxypropyl(meth)acrylate, 2-hydroxybutyl(meth)acrylate or so. Examples of (meth)acrylate containing glycidyl group include glycidyl(meth)acrylate or so. Examples of (meth)acrylate containing amino group include mono ethylamino(meth)acrylate, diethylamino(meth)acrylate or so. Examples of (meth)acrylate containing carboxyl group include 2-(meth)acryloyloxy ethyl phthalate, 2-(meth)acryloyloxy propyl phthalate or so.

In addition, monomer, (meth)acryl amide, vinyl acetate, styrene or so including a hydroxyl group other than (meth)acrylate, such as monomer, vinyl alcohol, N-methylol(meth)acryl amide or so including carboxyl group other than (meth)acrylate, such as (meth)acrylic acid, itaconic acid or so, may be copolymerized to acrylic polymer (A).

In case when including the below described crosslinking agent (G), acrylic polymer (A) is preferable to include a functional group, such as hydroxyl group, amino group, glycidyl group and carboxyl group, which react with crosslinking agent (G). Among all, acrylic polymer (A) including hydroxyl group is preferable; a production method thereof is easy, and it makes it easy to introduce cross linked structure by using crosslinking agent (G). In addition, the acrylic polymer including a hydroxyl group is excellent in compatibility with heat curable resin (B).

In case when the functional group reacting with crosslinking agent (G) is introduced to acrylic polymer (A) by using a monomer including the functional group reacting with crosslinking agent (G) as the monomer constituting acrylic polymer (A), a ratio of the monomer, including the functional group reacting with crosslinking agent (G), with respect to weight of all the monomers constituting acrylic polymer (A) is preferably around 1 to 20 wt %, and more preferably 3 to 15 wt %. By setting the constitutional unit derived from the monomer including a functional group reacting with crosslinking agent (G) in acrylic polymer (A) within the above range, the functional group reacting with crosslinking agent (G) and said crosslinking agent (G) are reacted forming a three dimensional network structure; and thus a crosslinking density of acrylic polymer (A) can be heightened. Consequently, the adhesive composition is capable of forming the single adhesive film or the adhesive layer superior in shear strength can be obtained. In addition, an absorbent of the adhesive composition decreases; and thus, the semiconductor device superior in package reliability can be obtained.

The acrylic polymer (A) is preferably included in the ratio of 50 wt % or more in the entire weight of the adhesive composition. With such constitution, acrylic polymer (A) shows preferable property when used for the process of simultaneous curing of the adhesive layer. This is because, even when the adhesive agent before curing is exposed to high temperature, it can maintain certain degree of hardness and wire bonding can be carried out. That is, when content of acrylic polymer (A) in the adhesive composition is relatively large, even if it is before heat curing, the storage elasticity of the adhesive layer can be maintained high. Therefore, even if the adhesive layer is before cured or semi-cured, vibration and displacement or so of the chip during wire bonding can be suppressed, and thereby wire bonding can be carried out stably. As such, if content of acrylic polymer (A) is increased in order to secure the process suitability, the amount of heat curable resin (B) decreases relatively. Therefore, the curing may be insufficient; however the adhesive composition of the present invention is capable of bonding the heat curable resin (B) and the filler having the reactive double bond group on the surface via the reactive double bond; thus the insufficient curing can be solved. The ratio of acrylic polymer (A), with respect to weight of all adhesive composition is preferably around 50 to 90 wt %, and more preferably 50 to 80 wt %. According to the first invention, an effect of the package reliability of the invention becomes remarkable by setting the ratio of acrylic polymer (A), having a weight average molecular weight (Mw) of 500,000 or more, within the above range.

(B) Heat curable resin including the reactive double bond group Heat curable resin (B) comprises the epoxy resin and the heat curing agent; and in the present invention, either one or both of the epoxy resin and the heat curing agent comprises the reactive double bond group. As for the epoxy resin, there are epoxy resin (B1) comprising the reactive double bond group and epoxy resin (B1′) which does not comprise the reactive double bond group; and as the heat curing agent, there are heat curing agent (B2) comprising the reactive double bond group and heat curing agent (B2′) which does not comprise the reactive double bond group. In the heat curable resin (B) of the present invention, either one of the epoxy resin (B1) comprising the reactive double bond group or heat curing agent (B2) comprising the reactive double bond group is included as the essential component. Also, either one of epoxy resin (B1) or epoxy resin (B1′) is included as the essential component; and either one of heat curing agent (B2) or heat curing agent (B2′) is included as the essential component. Note that, if both of the epoxy resin and the heat curing agent do not comprise the reactive double bond group, namely the combination only of the component (B1′) and the component (B2′) is excluded.

As the heat curable resin (B) comprises the reactive double bond group, it has high compatibility with the acrylic polymer (A) and the following described filler (C) compared to the heat curable resin which does not comprises the reactive double bond group. In addition, a three dimensional network structure is formed in the adhesive composition by causing an additional polymerization of the reactive double bond groups in the adhesive composition. Therefore, the adhesive composition of the present invention has improved reliability than the adhesive composition only including the heat curable resin which does not comprise the reactive double bond group as the heat curable resin.

The reactive double bond group is a functional group having a polymerizable carbon-carbon double bond; concrete examples thereof include vinyl group, allyl group, (meth)acryloyl group, (meth)acryloxy group or so; and the acryloyl group is preferable. Considering above, the reactive double bond groups of the invention do not include unpolymerizable double bond. For instance, component (B) may include aromatic ring; however, unsaturated structure of the aromatic ring is not the reactive double bond group of the present invention.

As for the epoxy resin (B1) having the reactive double bond group, the resin is preferable to include aromatic ring, since strength of the adhesive agent after heat curing and heat resistance are improved. Also, as the epoxy resin (B1) having the reactive double bond group, for example the compound wherein a part of the epoxy group of the polyvalent epoxy resin is converted to the group including the reactive double bond group may be mentioned. Such compound can be produced by carrying out an addition reaction of acrylic acid to epoxy group. Alternatively, the compound wherein the group including the reactive double bond group directly bonded to the aromatic ring or so constituting the epoxy resin may be mentioned.

Here, as the epoxy resin (B1) having the reactive double bond group, the compound shown in the following formula (1), the compound shown in the following formula (2), or the compound obtained by carrying out the addition reaction of the acrylic acid to a part of the epoxy group of the epoxy resin (B1′) which does not comprise the unsaturated hydrocarbon group which will be described in the below, or so may be mentioned.

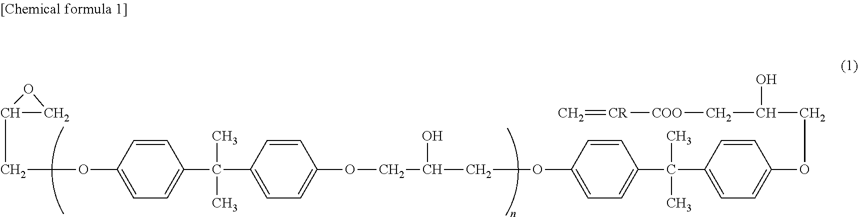

(R is H— or CH₃—, n is an integer of 0 to 10)

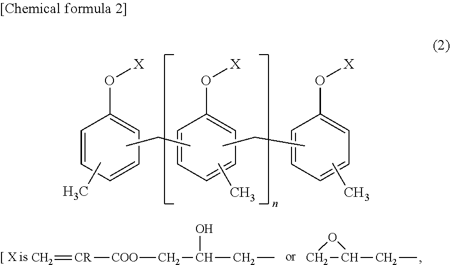

(X is H— or CH₃—, n is an integer of 0 to 10)

Note that, the epoxy resin (B1) having the reactive double bond group obtained by the reaction between the epoxy resin (B1′) which does not have the reactive double bond group and the acrylic acid may be the mixture between the unreacted material or the compound in which the epoxy group is completely consumed; however in the present invention, it only needs to substantially include the above mentioned compound.

As for the epoxy resin (B1′) which does not have the reactive double bond group, conventionally known epoxy resin can be used. As such epoxy resin, specifically, polyvalent epoxy resin or the epoxy compound comprising two or more functional groups in the molecule such as biphenyl compound, bisphenol A diglycidyl ether or the hydrogenates thereof, cresol novolac epoxy resin, dicyclopentadiene epoxy resin, biphenyl epoxy resin, bisphenol A epoxy resin, bisphenol F epoxy resin, phenylene backbone epoxy resin or so may be mentioned. These may be used alone or by combining two or more thereof.

The number average molecular weight of epoxy resin (B1) and (B1′) are not particularly limited; and in view of curability of the adhesive agent, and the strength and heat resistance after curing the adhesive agent, it is preferably 300 to 30,000, more preferably 400 to 10,000, and particularly preferably 500 to 3,000. Also, the content of the reactive double bond group in total amount of the epoxy resin [(B1)+(B1′)] is 0.1 to 1,000 mol, preferably 1 to 500 mol and more preferably 10 to 400 mol with respect to 100 mol of the epoxy group in total amount of the epoxy resin.

The heat curing agent functions as the curable agent against the epoxy resin (B1) and (B1′). According to the invention, either one of or both of heat curing agent (B2) which has the reactive double bond group and heat curing agent (B2′) which does not have the reactive double bond group are used as the heat curing agent. If the epoxy resin consists of epoxy resin (B1′) which does not have the reactive double bond group, heat curing agent (B2) which has the reactive double bond group is used as an essential component. If the epoxy resin includes the reactive double bond group, either one of or both of heat curing agent (B2) and heat curing agent (B2′) can be used.

The heat curing agent (B2) having the reactive double bond group is the heat curing agent including a polymerizable carbon-carbon double bond. The reactive double bond group includes preferably vinyl group, allyl group, (meth)acryloyl group, (meth)acryloxy group or so, and more preferably methacryloyl group. In addition, heat curing agent (B2) includes the functional group reactive to the epoxy group, in addition to the above reactive double bond group. Examples of the functional groups reactive to the epoxy group may include preferably phenolic hydroxy group, alcoholic hydroxy group, amino group, carboxyl group, acid anhydride or so; and among all, the phenolic hydroxy group, the alcoholic hydroxy group and the amino group are more preferable, and the phenolic hydroxy group is the most preferable.

As for the heat curing agent (B2) including the reactive double bond group, for example, the compound wherein a part of the hydroxyl group of the phenol resin being substituted by the group including the reactive double bond group, or the compound wherein the group including the reactive double bond group is directly bonded with the aromatic ring of the phenol resin or so may be mentioned. Here, as the phenol resin, the novolac phenol resin shown in the following formula (chemical formula 3), dicyclopentadiene phenol resin shown by (chemical formula 4), and the polyvalent phenol resin shown by (chemical formula 5) may be mentioned; and particularly novolac phenol resin is preferable. Therefore, as the heat curing agent (B2) including the unsaturated hydrocarbon group, for example, the compound wherein a part of the hydroxyl group of the novolac phenol resin being substituted by the group including the unsaturated hydrocarbon group, or the compound wherein the group including the unsaturated hydrocarbon group is directly bonded with the aromatic ring of the novolac phenol resin or so may be mentioned.

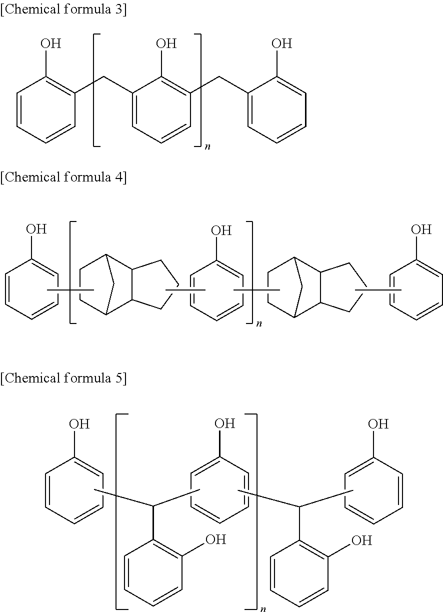

As particularly preferable example of the heat curing agent (B2) having the reactive double bond group, the structure wherein the reactive double bond group is introduced in a part of the repeating unit comprising the phenol hydroxyl group as such as the following formula (a), and the compound including the repeating unit comprising the group including the reactive double bond group such as the following formula (b) or (c) may be mentioned. Particularly preferable heat curing agent (B2) having the reactive double bond group includes the repeating unit of the following formula (a) and the following formula (b) or (c).

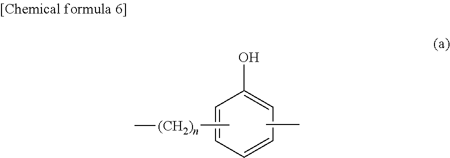

(“n” in the above formula is 0 or 1.)

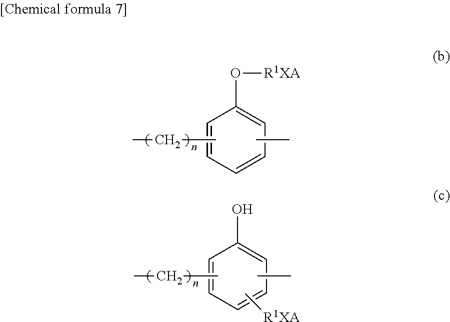

(In the formula, “n” is 0 or 1, “R¹” is hydrocarbon group having carbon atoms of 1 to 5, which may include the hydroxyl group, “X” is “—O—” or “—NR²—”, in which “R²” is hydrogen or methyl, or “R¹X” is a single bond. “A” is a (meth)acryloyl group.)

The phenolic hydroxyl group included in the repeating unit (a) is a functional group reactive with epoxy group, and functions as the curing agent, curable by reacting with the epoxy group of the epoxy resin during heat curing of the adhesive composition. The reactive double bond groups included in the repeating units (b) and (c) improve compatibility of acrylic polymer (A) and heat curable resin (B), and also form a three dimensional network in the adhesive composition by an additional polymerization of the reactive double bond groups. As a result, the cured product of the adhesive composition becomes tough, which improves reliability of the adhesive agent. In addition, the reactive double bond groups included in the repeating units (b) and (c) have an effect to lower adhesiveness between the adhesive layer and the support by polymerization curing during an energy ray curing of the adhesive composition. The ratio of the repeating unit shown by the above formula (a) in the heat curable resin (B2) is 5 to 95 mole %, more preferably 20 to 90 mole %, and the most preferably 40 to 80 mole %; a ratio of the repeating unit shown by the above formulas (b) and (c) in total is 5 to 95 mole %, more preferably 10 to 80 mole %, and the most preferably 20 to 60 mole %.

As heat curing agent (B2′) which does not have the reactive double bond group, a compound having two or more functional groups reactive with epoxy group in a molecule can be exemplified. Examples of such functional groups include phenolic hydroxy group, alcoholic hydroxy group, amino group, a carboxyl group, an acid anhydride or so; among all, the phenolic hydroxy group, the amino group and the acid anhydride are preferable, and the phenolic hydroxy group and the amino group are the most preferable. Hygroscopic of adhesive layers, including heat curing agent (amine based heat curing agent) having the amino group, becomes higher than that of adhesive layers, including a heat curing agent (phenol based heat curing agent) having the phenolic hydroxy group; and thus, adhesiveness to the adhesive layers under the heat and humidity conditions greatly lowers. While adhesive layers, including the phenol based heat curing agent show high wet heat resistance; and thus, adhesiveness to the adhesive layers under the heat and humidity conditions lowers in small amount. Thus, as heat curing agent (B2′), a compound including two or more phenolic hydroxy groups reactive with epoxy group is a molecule is preferable.

As the specific examples of the phenolic curing agent, polyvalent phenol resin, biphenol, novolac phenol resin, dicyclopentadiene phenol resin, aralkyl phenol resin or so may be mentioned. As the specific examples of the amine curing agent, DICY (dicyandiamide) may be mentioned. These may be used alone or two or more may be combined.

The number average molecular weight of the above heat curing agent (B2) and (B2′) is preferably 40 to 30,000, more preferably 60 to 10,000, and the most preferably 80 to 3,000.

The content amount of the above heat curing agents [(B2) and (B2′)] in the adhesive composition, with respect to 100 parts by weight of epoxy resin, is preferably 0.1 to 500 parts by weight and more preferably 1 to 200 parts by weight. In addition, a content amount of the heat curing agents [(B2) and (B2′)] is preferably 5 to 50 parts by weight, and more preferably 10 to 40 parts by weight, with respect to 100 parts by weight of acrylic polymer (A). By setting the content amounts of heat curing agent in the adhesive composition and in acrylic polymer (A) within the above range, package reliability becomes superior.

The ratio of heat curable resin (B) (a total of epoxy resin and heat curing agent [(B1)+(B1′)+(B2)+(B2′)]), with respect to a total weight of the adhesive composition, is preferably less than 50 wt %, more preferably 1 to 30 wt %, and further preferably 5 to 25 wt %. Further, in the adhesive composition, with respect to 100 parts by weight of acrylic polymer (A), heat curable resin (B) is included within a range of preferably 1 part by weight or more and less than 100 parts by weight, more preferably 3 to 60 parts by weight, and further preferably 3 to 40 parts by weight. If the content amount of heat curable resin (B) is excessively low, sufficient adhesiveness cannot be obtained, while if excessively high, releasing strength between the adhesive layer and the support becomes high, causing pickup deficiency.

(C) Filler Having the Reactive Double Bond Group Thereon

Filler (C) having the reactive double bond thereon is not particularly limited, as long as it includes a reactive double bond group thereon. The reactive double bond group is preferably vinyl group, allyl group, (meth)acryloyl group or (meth)acryloxy group.

The above described filler is preferably surface treated by a compound including the reactive double bond group.

As material of the filler (untreated filler), silica, alumina, calcium carbonate, calcium silicate, magnesium hydroxide, aluminum hydroxide, titanium oxide, carbon black, talc, mica, or clay or so may be mentioned. Among these, silica is preferable. The silanol group included in silica effectively acts on the binding between the silane coupling agent.

The filler having the reactive double bond group on the surface is obtained, for example, by surface treating the surface of the untreated filler by the coupling agent comprising the reactive double bond group.

The coupling agent having reactive double bond groups is not particularly limited. As for the coupling agent, for instance, the coupling agent including vinyl group, the coupling agent including styryl group, and the coupling agent including (meth)acryloxy group are suitably used. The above coupling agent is preferably the silane coupling agent.

As for the above coupling agent, specifically, vinyltrimethoxysilane, vinyltriethoxysilnae, p-styryltrimethoxysilane, 3-methacryloxypropyldimethoxysilane, 3-methacryloxypropyltrimethoxysilane, 3-methacryloxypropyltriethoxysilane, 3-methacryloxypropylmethyldiethoxysilane, 3-acryloxypropyltrimethoxysilane, or so may be mentioned. Commercial products thereof are KBM-1003, KBE-1003, KBM-1403, KBM-502 and KBM-503, KBE-502, KBE-503, KBM-5103, all made by Shin-etsu Chemical Co., Ltd., may be mentioned.

The surface treating method of the above mentioned filler by the coupling agent is not particularly limited. As for the method, there may be mentioned a dry method in which untreated filler is added to a mixer, which enables a high-speed rotation such as Henschel mixer or V-type mixer, and then, while stirring, the coupling agent is added directly thereto or added after dissolved and dispersed in an alcohol solution, an organic solvent or an aqueous solution. Further, the direct treating method such as the slurry method wherein the coupling agent is added in the slurry of the untreated filler or the spray method providing the spray of the coupling agent after the untreated filler is dried or so; and the integral blend method or so wherein the untreated filler and the acrylic polymer are blended when preparing the above mentioned composition, and directly adding the coupling agent when mixing may be mentioned.

The lower limit of the preferable amount of the coupling agent for surface treating 100 parts by weight of the above mentioned untreated filler is 0.1 parts by weight, and the preferable upper limit is 15 parts by weight.

Although an average particle diameter of the above filler according to the first invention is not particularly limited, it is preferably within a range of 0.01 to 2 μm. If the average particle diameter of the filler is within such preferable range, adhesiveness can be exhibited without losing lamination property to the adherend. Further, specially, in case when the chip is placed on the adherend, such as the circuit board or other chip, reliability improvement effect of the adhesive composition of the invention is remarkably shown. According to the first invention, when the average particle diameter of the filler is more than 0.2 μm and 2 μm or less, surface conditions of a single layer adhesive film or an adhesive sheet of the invention may deteriorate and lamination property to the adherend may become worth; however, with the use of the acrylic polymer (A) having a weight average molecular weight of 500,000 or more, viscosity of the adhesive composition improves, and consequently, prevents lamination property to the adherend from lowering. If the above average particle diameter is over 2 μm, surface conditions of the single layer adhesive film or the adhesive sheet of the invention may deteriorate, lamination property to the wafer may deteriorate, and an in-plain thickness of the adhesive layer may disperse. Note that the above “the average particle diameter” is obtained by a particle size distribution meter (made by Nikkiso Co., Ltd.; Name of the device: Nanotrac 150) using a dynamic light scattering method (The same hereinafter).

Average particle diameter of the above filler according to the second invention is within a range of 0.01 to 0.2 μm. If the average particle diameter of the filler is within the above described range, adhesiveness can be exhibited without losing lamination property to the adherend. Further, specially, in case when the chip is placed on the adherend, such as the circuit board or other chip, reliability improvement effect of the adhesive composition of the invention is remarkably shown. If the above average particle diameter is excessively large, there may generate defects: the surface condition of the sheet may deteriorate; an in-plain thickness of the adhesive layer may disperse; and shear strength of the cured products of the adhesive composition may decrease; and so on. By setting the average particle diameter of the filler of the second invention within the above range, reliability improvement effect of the adhesive composition is remarkably shown; this is assumed by the following reason. If the particle diameter of the filler is large, the structure formed by components other than the filler filling gaps between the fillers also becomes large. Cohesion property of the components other than the filler is lower than the same of the filler. If the structure formed by components other than the filler is large, a fracture generated to the components other than the filler might spread widely. While the filler is fine in size, the structure formed by components other than filler also becomes fine. In this case, the filler taken into said fine structure prevent progression of the fracture, even when the fracture is generated to the components other than the filler. Consequently, there is a tendency of the fracture not to spread. In addition, in the invention, the reactive double bond group of methacryloxy group or so included in the filler and the reactive double bond group of B1 component or so included in the components other than the filler are capable to form bond. If the filler is fine in size, contact areas of the filler and components other than the filler become large. Consequently, bonds between the filler and B1 component tend to increase.

The above filler (C), having the reactive double bond groups on surface thereof, are superior in affinity with acrylic polymer (A) and heat curable resin (B), and is capable of uniform dispersion in the adhesive composition.

The above filler (C), with respect to a total weight of the adhesive composition, is preferably less than 50 wt %, more preferably 1 to 30 wt %, and further preferably 5 to 25 wt %. Further, with respect to 100 parts by weight of acrylic polymer (A) and heat curable resin (B), the above filler (C) is included within a range of preferably 5 parts by weight or more and less than 100 parts by weight, more preferably 8 to 60 parts by weight, and further preferably 10 to 40 parts by weight. If an amount of the above filler is excessively high, lamination property to the wafer or adhesiveness to the support may be deteriorated; while when excessively low, effect of the filler addition may not be sufficiently exhibited.

If the adhesive layers include the filler (C) within such range, even when the adhesive layers are uncured or semi-cured, said adhesive layers show an elastic modulus having enough durability for the vibration during wire bonding. Thus, vibration and displacement of chips during wire bonding do not occur, so that the wire bonding can be safely performed, enhancing the effect of the invention.

Other Components

The adhesive composition may include the following components in addition to the above components.

(D) The Photopolymerization Initiator

The adhesive composition is preferable to include the photopolymerization initiator. Inclusion of the photopolymerization is, in case when using the adhesive sheet of the invention as dicing and die bonding sheet, laminating the sheet to the wafer, and irradiating ultraviolet ray before the dicing step, capable of causing reaction between the reactive double bond groups included in heat curable resin (B) and filler (C) leading to a pre-curing thereof. By performing pre-curing, lamination property to the wafer becomes superior since the adhesive layers are relatively softened before curing, and the sheet shows an appropriate hardness during dicing and that an attachment of the adhesive agent to a dicing blade and other problems can be suppressed. In addition, it becomes possible to control releasing property of an interface of the support (the resin film or the sticky sheet) and the adhesive agent. Further, hardness of pre-cured state becomes higher than that of uncured state, thus, the pre-cured state improves stability during wire bonding.

As for the photopolymerization initiator (D), benzophenon, acetophenon, benzoin, benzoinmethylether, benzoinethylether, benzoinisopropylether, benzoinisobutylether, benzoin bezoic acid, benzoin methyl benzoic acid, benzoindimethylketal, 2,4-diethylthioxanthone, α-hydroxycyclohexylphenylketone, benzyldiphenylsulfide, tetramethylthiurammonosulfide, azobisisobutylnitrile, benzyl, dibenzyl, diacetyl, 1,2-diphenylmethane, 2-hydroxy-2-methyl-1-[4-(1-methylvinyl)phenyl]propanone, 2,4,6-trimethylbenzoildiphenylphosphinoxide, β-chloranthraquinone or so may be mentioned. The photopolymerization initiator (D) may be used alone or by combining two or more.

In case of using photopolymerization initiator (D), the blending ratio thereof may be determined accordingly based on the total amount of the reactive double bond group of the filler surface and the unsaturated hydrocarbon group of the heat curable resin. Although, it is not limited thereto, for example, with respect to total 100 parts by weight of heat curable resin (B) and filler (C), photopolymerization initiator (D) is usually 0.1 to 10 parts by weight, and preferably 1 to 5 parts by weight. If the content of photopolymerization initiator (D) is less than the above mentioned range, a sufficient reaction may not be obtained due to the insufficient photopolymerization, and if it exceeds the above mentioned range, the residue which does not contribute to the photopolymerization is generated, and the curability of the adhesive composition may be insufficient.

(E) Curing Accelerator

Curing accelerator (E) is used to regulate curing speed of the adhesive composition. As for the preferable curing accelerator, tertiary amines including triethylenediamine, benzyldimethylamine, triethanolamine, dimethylaminoethanol, tris(dimethylaminomethyl)phenol or so; imidazoles including 2-methylimidazole, 2-phenylimidazole, 2-phenyl-4-methylimidazole, 2-phenyl-4,5-dihydroxymethylimidazole, 2-phenyl-4-methyl-5-hydroxymethylimidazole or so; organic phosphines including tributylphosphine, diphenylphosphine, triphenylphosphine or so;_tetraphenylboron salt including tetraphenylphosphoniumtetraphenylborate, triphenylphosphinetetraphenylborate or so, may be mentioned. These may be used alone or by combining two or more thereof.

In case of using curing accelerator (E), with respect to 100 parts by weight of heat curable resin (B) in total [(B1)+(B1′)+(B2)+(B2′)], said curing accelerator (E) is included in an amount of preferably 0.01 to 10 parts by weight, and more preferably 0.1 to 1 parts by weight. By including the curing accelerator (E) in the amount of the above mentioned range, even if it is exposed under high temperature high humidity, an excellent adhesiveness can be exhibited, and also even if it is exposed to a harsh reflow condition, the high package reliability can be attained. If the content of the curing accelerator (E) is too small, a sufficient adhesive characteristic cannot be obtained due to the insufficient curing, and if it is too much, the curing accelerator having high polarity moves in the adhesive layer towards the adhesive boundary side at high temperature high humidified condition, and segregates thereby lowers the package reliability.

(F) Coupling Agent

Coupling agent (F) includes the functional group reactive with inorganics and the functional group reactive with an organic functional group; thus, coupling agent (F) can be used to improve lamination property and adhesiveness to the adherend of adhesive layers. Further, with the use of a coupling agent (F), water resistance property of cured product obtained by curing adhesive layers can be improved without losing heat resistance property thereof.

As for the coupling agent (F), silane coupling agent is preferable. Such coupling agent includes the low molecular silane coupling agent having 2 or 3 alcoxy groups such as γ-glycidoxypropyltrimethoxysilane, γ-glycidoxypropyltriethoxysilane, γ-glycidoxypropylmethyldiethoxysilane, β-(3,4-epoxycyclohexyl)ethyltrimethoxysilane, γ-(methacrylopropyl)trimethoxysilane, γ-aminopropyltrimethoxysilane, N-6-(aminoethyl)-γ-aminopropyltrimethoxysilane, N-6-(aminoethyl)-γ-aminopropylmethyldiethoxysilane, N-phenyl-γ-aminopropyltrimethoxysilane, γ-ureidepropyltriethoxysilane, γ-mercaptopropyltrimethoxysilane, γ-mercaptopropylmethyldimethoxysilane, methyltrimethoxysilane, methyltriethoxysilane, vinyltrimethoxysilane, or so; the low molecular silane coupling agent having 4 alcoxy groups such as tetramethoxysilane, tetraethoxysilane or so; bis(3-triethoxysilylpropyl)tetrasulfane, vinyltriacetoxysilane, imidazolsilane or so. In addition, oligomer type compounds of condensed product, formed by hydrolysis and dehydration condensation of the alcoxy group included in the low molecular silane compound having 2 or 3 alcoxy groups and in the low molecular silane coupling agent having 4 alcoxy groups, are exemplified as the coupling agent. Particularly, among the above low molecular silane coupling agent, the oligomer of the condensed compound formed by the dehydration condensation of the low molecular silane compound having 2 or 3 alcoxy groups and the low molecular silane compound having 4 alcoxy groups has good reactivity of the alcoxy group and has sufficient number of the organic functional group thus it is preferable, for example, oligomer of the copolymer of 3-(2,3-epoxypropoxy)propylmethoxysiloxane and dimethoxysiloxane may be mentioned. These may be used alone or by combining two or more. In addition, among these, a compound having the group reactive with the functional group included in such as the above acrylic polymer (A) and heat curable resin (B).

When using the coupling agent (F), the coupling agent (F) is included usually 0.1 to 20 parts by weight, preferably 0.2 to 10 parts by weight, and more preferably 0.3 to 5 parts by weight with respect to total 100 parts by weight of acrylic polymer (A) and heat curable resin (B). If the content of coupling agent (F) is less than 0.1 parts by weight, the above mentioned effect may not be obtained, and if it exceeds 20 parts by weight, then it may cause volatile gas.

(G) Crosslinking Agent

In the adhesive composition, in order to regulate the initial adhesive force and the cohesion of the adhesive layer, the crosslinking agent (G) can be added. Note that, when blending the crosslinking agent, said acrylic polymer (A) includes the functional group which reacts with the crosslinking agent. As for the crosslinking agent (G), organic polyvalent isocyanate compound, organic polyvalent imine compound or so may be mentioned.

As for the above mentioned organic polyvalent isocyanate compound, the aromatic polyvalent isocyanate compound, aliphatic polyvalent isocyanate compound, alicyclic polyvalent isocanate compound and the trimer of these organic polyvalent isocyanate compound, and an end terminal isocyanate urethane prepolymer or so obtained by reacting these organic polyvalent isocyanate compound and polyol compound can be mentioned.

As for the organic polyisocyanate compounds, 2,4-tolylene diisocyanate, 2,6-tolylene diisocyanate, 1,3-xylylene diisocyanate, 1,4-xylylene diisocyanate, diphenylmethane-4,4′-diisocyanate, diphenylmethane-2,4′-diisocyanate, 3-methyldiphenylmethane diisocyanate, hexamethylene diisocyanate, isophorone diisocyanate, dicyclohexylmethane-4,4′-diisocyanate, dicyclohexylmethane-2,4′-diisocyanate, trimethylolpropane adduct tolylenediisocyanate, lysine isocyanate or so may be mentioned.

In case of using the isocyanate based crosslinking agent, as for the acrylic polymer (A), it is preferable to use the hydroxyl group containing polymer. If the crosslinking agent comprises the isocyanate group and the acrylic polymer (A) comprises the hydroxyl group, the reaction between the acrylic polymer (A) and the crosslinking agent may take place, thereby the crosslinking structure can be easily introduced into the adhesive agent.

As for the organic polyimine compounds, N,N′-diphenylmethane-4,4′-bis(1-aziridinecarboxyamide), trimethylolpropane-tri-β-aziridinyl propionate, tetramethylolmethane-tri-β-aziridinyl propionate, N,N′-toluene-2,4-bis(1-aziridinecarboxyamindo)triethylenemelamine or so may be mentioned.

In case of using the crosslinking agent (G), the crosslinking agent (G) is used in the ratio of usually 0.01 to 20 parts by weight, preferably of 0.1 to 10 parts by weight, more preferably of 0.5 to 5 parts by weight with respect to 100 parts by weight of acrylic polymer (A).

(H) Energy Ray Polymerizable Compound

In the adhesive composition, the energy ray polymerizable compound may be blended. The energy ray polymerizable compound (H) includes the energy ray polymerizable group; and polymerizes and cures when the energy ray such as ultraviolet ray, electron beam or so are irradiated. As for energy ray polymerizable compound (H), trimethylolpropane-triacrylate, pentaerythritol-triacrylate, pentaerythritol-tetraacrylate, dipentaerythritol monohydroxy-pentaacrylate, dipentaerythritol hexaacrylate or 1,4-butylene glycol diacrylate, 1,6-hexanediol diacrylate, polyethylene glycol diacrylate, oligoester acrylate, urethane acrylate based oligomer, epoxy modified acrylate, polyether acrylate, acrylate based compounds such as itaconic oligomer or so may be mentioned. Such compound includes at least one polymerizable carbon-carbon double bond in a molecule; and normally, weight average molecular weight is 100 to 30,000, preferably 300 to 10,000. If energy ray polymerizable compound (H) is used, a compound amount thereof is not particularly limited; however, it is preferably used within the ratio of around 1 to 50 parts by weight, with respect to 100 parts by weight of the total amount of the adhesive composition on the solid basis.

(I) Thermoplastic Resin

The adhesive composition may include polymer other than acrylic polymer (A). As such polymer, the thermoplastic resin (I) may be used. The thermoplastic resin (I) is blended in order to maintain flexibility of the adhesive layer after curing. As for the thermoplastic resin (I), it is preferable to have the weight average molecular weight of 1,000 to 100,000, and more preferably 3,000 to 80,000. By comprising the thermoplastic resin (I), the layer releasing between the support and the adhesive layer can be carried out easily during the pickup step of the semiconductor chip, and further the adhesive layer follows roughness of the circuit board and enables to suppress generation of voids or so.

Glass transition temperature of heat curable resin (I) is preferably within −30 to 150° C., and more preferably −20 to 120° C. In case when glass transition temperature of thermoplastic resin (I) is too low, releasing strength between adhesive layers and support becomes large and may cause pickup deficiency; while when too large, adhesive force fixing wafer may become insufficient.

As for thermoplastic resin (I), polyester resin, urethane resin, phenoxy resin, polybutene, polybutadiene, polystyrene or so may be mentioned. These may be used alone or by combining two or more.

In case of using thermoplastic resin (I), the blending amount thereof is preferably within the range of 1 to 300 parts by weight, more preferably 2 to 100 parts by weight with respect to total 100 parts by weight of acrylic polymer (A) and heat curable resin (B). If content of the thermoplastic resin (I) is within this range, the above mentioned effect can be obtained.

(J) Other Inorganic Fillers

Also, in the adhesive composition, other than the above mentioned filler (C), the inorganic filler (J) may be blended as the filler which does not have the reactive double bond. As for the inorganic filler, the powder of silica, talc, calcium carbonate, titanium white, indian red, silicon carbide, boron carbide or so; the beads of made by spheroidizing these, single crystal fiber and glass fiber or so may be mentioned.

(K) General Additives

In the adhesive composition, other than the above mentioned, various additives may be blended if needed. As for such various additives, plasticizers, antistatic agents, antioxidants, pigments, colorings, gettering agents or so may be mentioned.

### (The Adhesive Sheet)

The adhesive layers made by adhesive compositions including each component above show adhesiveness, such as heat-sensitive adhesiveness and pressure-sensitive adhesiveness, and thermosetting property. If adhesive layers show pressure-sensitive adhesiveness, it can be pressed and laminated to adherend when in uncured state. Further, if adhesive layers show heat-sensitive adhesiveness, the adhesive layer can be heated and laminated when pressing to adherend. “Heat-sensitive adhesiveness” in the invention defines that there is no pressure-sensitive adhesiveness at normal temperature; while it is capable to adhere to adherend when heated and softened. Also, as the filler is uniformly dispersed in the adhesive layer, even at high temperature for adhering the semiconductor chip and carrying out the wire bonding, the adhesive layer has only little deformation; and the wire bonding can be carried out stably. Further, after going through the heat curing, at the end, a cured product having high impact resistance can be provided, has excellent shear strength, and sufficient adhesive characteristic can be maintained even under harsh high temperature high humidified condition. In case the photopolymerization initiator (D) is included, it comprises the energy ray curable property, and the pre-curing can be carried out by irradiating the energy ray before the thorough curing. Due to the pre-curing, the hardness of the adhesive layer increases, and the stability during the wire bonding improves.

The adhesive sheet may be the adhesive film of the single layer in which the above mentioned adhesive composition is made into a film; however preferably it is the adhesive sheet wherein the adhesive layer comprising the above mentioned adhesive composition is formed on the support in a releasable manner. Particularly, shear strength of the single adhesive film made by the adhesive composition according to the second invention, after curing at 250° C., is preferably 60N/5 mm□ or more, more preferably 70N/5 mm□ to 150N/5 mm□, further preferably 80N/5 mm□ to 120N/5 mm□. In addition, shear strength of the adhesive sheet, having the adhesive layer made by the adhesive composition according to the second invention, after curing at 250° C., is preferably 60 N/5 mm□ or more, more preferably 70N/5 mm□ to 150N/5 mm□, further preferably 80N/5 mm□ to 120N/5 mm□.

Hereinafter, taking an example of the adhesive sheet in which the adhesive layer is releasably formed on the support, its preferred embodiment and a use embodiment are described. In case when using the adhesive sheet in which the adhesive layer is releasably formed on the support, the adhesive layer is laminated to the adherent, such as wafer, chip or so, the support is released, the adhesive layer is transferred to the adherent. Formation of the adhesive sheet of the invention can be varied in all kinds, such as a tape form. The support can be a resin film without a tuck on the surface thereof, and can be the sticky sheet in which the sticky agent layer is provided on a resin film.

As for the resin film used for the support of the resin sheet, for example, a transparent film such as polyethylene film, polypropylene film, polybutene film, polybutadiene film, polymethylpentene film, polyvinyl chloride film, vinyl chloride copolymer film, polyethylene telephthalate film, polyethylenenaphthalate film, polybutylenetelephthalate film, polyurethane film, ethylene acetate vinyl copolymer film, ionomer resin film, ethylene/(meth)acrylate copolymer film, ethylene/(meth)acrylate ester copolymer film, polystyrene film, polycarbonate film, poly imide film or so, or a crosslinking film of these transparent film may be mentioned. Also, it may be a multistacked film thereof. Further, the colored film thereof and non-transparent film or so can be used.

The adhesive sheet of the present invention is laminated on various adherends, the predetermined processes are performed to the adherend, and then the adhesive layer is released from the support while the adhesive layer is transferred to the adherend. That is, the adhesive sheet is used in the processes including the step of transferring the adhesive layer to the adherend from the support. Therefore, the surface tension of the side contacting the adhesive layer of the support is preferably 40 mN/m or less, more preferably 37 mN/m or less, and particularly preferably 35 mN/m or less. The lower limit is generally around 25 mN/m. The resin film with such relative low surface tension can be obtained by appropriately selecting the material, and also by coating the releasing agent to the surface of the resin film; that is, by performing the releasing treatment.

As for the releasing agent used for the releasing treatment of the resin film, releasing agents such as alkyd base, silicone base, fluoride base, unsaturated polyester base, polyolefin base, wax base or so may be mentioned; among these, from the point of view of comprising the heat resistance property, the releasing agents such as the alkyd base, silicone base, fluoride base are preferable.

In order to carry out the releasing treatment to the surface of the resin film using the above releasing agent, the releasing agent is coated as it is with no solvent included or under the condition being diluted by the solvent or emulsified condition, using the gravure coater, the Mayer bar coater, the air knife coater, roll coater or so. Then the resin film coated with the releasing agent is cured by setting to the room temperature or the heating temperature, or by irradiating electron beam or ultraviolet ray. Surface tension of the resin film may be adjusted by a wet lamination or dry lamination, a heat melting lamination, a melt extrusion lamination, a coextrusion process or so.

If the sticky sheet is used as the support, said sticky sheet may be used as a dicing sheet. The dicing sheet includes the sticky agent layer on the resin film such as described in the above, and on the sticky agent layer, said adhesive layer is stacked in a releasable manner. Therefore, the sticky agent layer of the dicing sheet can be constituted from the known sticky agent having releasable property; and the sticky agent of ultraviolet ray curable type, heat foaming type, water swelling type, and weak adhesive type can be selected; thereby the releasing of the adhesive layer can be made easy.

In addition, the adhesive sheet may be shaped by preliminary punching the support and the adhesive layer to a shape equivalent to that of the adherent, such as semiconductor wafer or so. Particularly, the support and the multilayer body made by the adhesive layer is preferably retained on a long releasing film.

The thickness of the support is usually 10 to 500 μm, preferably 15 to 300 μm, and particularly preferably 20 to 250 μm or so. If the support is the sticky sheet, the layer made from the sticky agent is generally 1 to 50 μm or so in the thickness of the support. Also, the thickness of the adhesive layer is usually 2 to 500 μm, preferably 6 to 300 μm, and particularly preferably 10 to 150 μm or so.

The production method of the adhesive sheet is not particularly limited, and in case the support is the resin film, the adhesive composition is pasted and dried on the resin film to form the adhesive layer; thereby it may be produced. Also, the adhesive sheet may be produced by providing the adhesive layer on other releasing film, and transferring this to above mentioned resin film or sticky sheet.

Note that, before using the adhesive sheet, in order to protect the adhesive layer, the releasing film may be stacked on the surface of the adhesive layer. As the releasing film, those of which the releasing agent such as silicone resin or so are coated on the plastic material such as polyethylenetelephthalate film or polypropylene film or so is used. Also, at the outer peripheral part of the surface of the adhesive sheet, additional sticky agent layer or the sticky tape may be provided in order to fix other jigs such as ring flame or so.

Next, in regards with the method of use of the adhesive sheet according to the present invention, it will be explained taking the case of using the adhesive sheet to the production of the semiconductor device as an example.

### (Production Method of the Semiconductor Device)

Hereinafter, the production method of the semiconductor device according to the present invention will be described. The first production method of the semiconductor device according to the present invention includes the steps of; adhering the adhesive layer of the adhesive sheet on a semiconductor wafer, dicing said semiconductor wafer and the adhesive layer, thereby obtaining a semiconductor chip, releasing the semiconductor chip from the support while the adhesive layer is transferred to backside of said semiconductor chip, and adhering said semiconductor chip on a die pad portion of organic circuit board or lead frame or on other semiconductor chip via said adhesive layer.

In the first production method of the semiconductor device according to the present invention, first, the semiconductor wafer is prepared wherein the circuit is formed on the frontside and the backside has been ground.

The semiconductor wafer can be silicon wafer, or it may be a compound semiconductor wafer such as gallium.aresenic. The circuit is formed in the wafer frontside by various methods including the conventionally widely used method such as an etching method, a lift off method or so. Next, the opposite side (backside) of the circuit face of semiconductor wafer is ground. The grinding method is not particularly limited, and it may be ground by known means such as grinder or so. When carrying out the backside grinding, in order to protect the circuit on the frontside, the sticky sheet so called surface protection sheet is laminated to the circuit surface. The backside grinding is carried out by fixing the circuit face side of the wafer (that is the surface protection sheet side) to the chuck table or so, and then the backside which is not formed with the circuit is ground. The thickness after the wafer grinding is not particularly limited, however usually it is 20 to 500 μm or so.

Next, the ring frame and the backside of the semiconductor wafer are placed on the adhesive layer of the adhesive sheet according to the present invention, and then lightly pressed; thereby the semiconductor wafer is fixed. Next, in case the photopolymerization initiator (D) is blended to the adhesive layer, the energy ray is irradiated to the adhesive layer from the support side, and the reactive double bond group in heat curable resin (B) and in filler (C) are reacted and cured; thereby the cohesion of the adhesive layer is increased and the adhesive force between the adhesive layer and the support is made low. As for the energy ray being irradiated, the ultraviolet ray (UV), or the electron beam (EB) or so may be mentioned; and preferably the ultraviolet ray is used. Next, by using blade dicing method using dicing saw, laser dicing method using laser beam or so, the above mentioned semiconductor wafer is cut and the semiconductor chip is obtained. The depth of the cut, when dicing saw is used, is determined considering the total of the thickness of the semiconductor wafer and the thickness of the adhesive layer, and also the abrasion of the dicing saw; and the adhesive layer is also cut as the same size as the chip. Note that, the energy ray irradiation may be carried out any time between after the semiconductor wafer is laminated and before the semiconductor chip is released (pickup); and for example, it may be carried out after the dicing and it may be carried out after the following described expanding step. Further, the energy ray irradiation can be carried out in plurality of times.

Next, if needed, by carrying out the expanding of the adhesive sheet, the space between the semiconductor chips is made wider; thereby pickup of the semiconductor chip can be carried out easily. At this time, the adhesive layer and the support slides against each other and the adhesive force between the adhesive layer and the support declines, thereby pickup property of the semiconductor chip improves. By carrying out pickup of the semiconductor chip as such, the semiconductor chip can be released from the support while the adhesive layer being cut is transferred on backside of the semiconductor chip.

Next, the semiconductor chip is placed on the surface of the die pad of the lead frame or on other semiconductor chip (lower chip) which is the chip mounting part, and the chip is temporally adhered. The chip mounting part may be heated before the semiconductor chip is placed thereon or immediately after the semiconductor chip is placed thereon; and the chip is temporary adhered. The heating temperature is usually 80 to 200° C., preferably 100 to 180° C.; and the heating time is usually 0.1 seconds to 5 minutes, and preferably 0.5 seconds to 3 minutes. The pressure when placing the chip is usually 1 kPa to 200 MPa.

It is preferable to stack the chip sequentially while the chip is temporary adhered, and carry out the thorough curing of the adhesive layer by using the heating of the resin sealing which is usually carried out during the package production. By going through such steps, the adhesive layer can be cured simultaneously thereby the production efficiency improves. Also, when carrying out the wire bonding, the adhesive layer is carried out with the pre-curing, thus the wire bonding can be carried out stably. Further, the adhesive layer is softened under the die bonding condition, thus it is embedded into the roughness of the chip mounting portion, and the void is prevented from being generated thus the package reliability increases.

In the second production method of the semiconductor device according to the present invention, first, a semiconductor wafer is separated into individual semiconductor chips by forming a groove from the surface of the semiconductor wafer along an outline of a shape of the separating semiconductor chip, laminating a protective sheet on the surface of the semiconductor wafer, and then performing a thinning treatment from the rear surface until reached to the groove; a plurality of chip group is prepared by so called dicing before grinding method.

Next, similar to the first production method, the ring frame and the backside of the chip group are placed on the adhesive layer according to the present invention, and then lightly pressed; thereby the chip group is fixed. Subsequently, only the adhesive layer is diced to the chip size. The method of dicing only the adhesive layer is not particularly limited; however, laser dicing method or so may be used.

Subsequently, expanding the adhesive sheet if needed, releasing semiconductor chip from the support while the adhesive layer is transferred on the semiconductor chip, and placing the semiconductor chip on the die pad or on other semiconductor chip via adhesive layer are similar to the first production method described above.

The adhesive composition and the adhesive sheet of the present invention can be used for the adhering the semiconductor compound, glass, ceramics, metals or so in addition to the above mentioned method of use.

### Examples

Hereinafter, the present invention will be explained using the examples; however the present invention is not to be limited thereto. Note that, in the below examples and the comparative examples, “measurements of acrylic polymer weight average molecular weight and acrylic polymer molecular weight distribution”, “shear strength mesaurement”, and “package reliability evaluation” were carried out as following. Note, the shear strength measurement was carried out to examples (Ex. 3, 4 and Comp. Ex. 3, 4) of the invention according to the second invention.

### <Measurements of Acrylic Polymer Weight Average Molecular Weight and Acrylic Polymer Molecular Weight Distribution>

Weight average molecular weight (Mw) and molecular weight distribution (Mw/Mn, Mn is number-average molecular weight) of acrylic polymer (A) are the values in terms of standard polystyrene, and measured by the following device and conditions.

Device Name: HLC-8220GPC, made by Tosoh Corp.
Column: TSKgelGMHXL, TSKgelGMHXL and TSKgel2000HXL were connected in this order

### Solvent: Tetrahydrofuran

Measurement temperature: 40° C.
Current: 1 ml/minute
Detector: differential refractometer

### <Average Particle Diameter of the Filler>

Average particle diameter of the filler was measured by the particle size distribution meter (Device Name: Nanotrac 150 made by Nikkiso Co., Ltd.) using dynamic light scattering method.

### <Shear Strength Measurement>

### (Producing Evaluation Sample)

To the brushed face of the silicon wafer (diameter of 150 mm, thickness of 350 μm) brushed with #2000, the lamination of the adhesive sheet of the examples and the comparative examples were carried out by the tape mounter (Adwill RAD 2500 made by Lintec Corporation) thereby it was fixed to the ring frame for wafer dicing. Then, by using the dicing device (DFD651 made by DISCO Corporation), the chip was diced into the size of 5 mm×5 mm. The cut during the dicing was made to cut 20 μm into the support. As for the lower chip, temporally adhered to the upper chip, CMP treated chip (size: 10 mm×10 mm, thickness: 350 μm) was prepared. Onto the lower chip, at 150° C., 100 gf, 1 sec. via adhesive layer, the above obtained chip was pressure bonded. Assuming mold sealing of the semiconductor package, heat curing of adhesive layer was performed at 175° C. for 5 hours; thus producing evaluation samples.

### (Evaluation)

The evaluation sample was placed on a plate of 250° C., assuming the temperature during reflow, and the shearing strength was measured under an environmental condition of humidity at 50% RH, using bond tester (dage 4000 made by Dage Corp.). The setup condition of the bond tester was head height of 50 μm and rate of 0.2 mm/sec.

### <The Package Reliability Evaluation>

### (The Production of the Semiconductor Chip)

To the brushed face of the silicon wafer (diameter of 150 mm, thickness of 75 μm) finished with dry polishing, the lamination of the adhesive sheet of the examples and the comparative examples were carried out by the tape mounter (Adwill RAD 2500 made by Lintec Corporation) thereby it was fixed to the ring frame for wafer dicing. Then, by using the dicing device (DFD651 made by DISCO Corporation), the chip was diced into the size of 8 mm×8 mm. The cut during the dicing was made to cut 20 μm into the support.

(The Production Method of the Semiconductor Package)

The circuit board comprising the circuit pattern formed on the copper foil (18 μm thickness) of the copper clad laminates (CCL-HL830 made by MITSUBISHI GAS CHEMICAL COMPANY. INC), and comprising a solder resist (PSR-4000 AUS303 made by TAIYO INK MFG. CO. LTD) on the pattern was used. The chip on the adhesive sheet obtained in the above was taken out together with the adhesive layer from the support, and pressure adhered on the circuit board at 120° C., 250 gf, for 0.5 second via the adhesive layer.

Then, the stacked body consisting of circuit board, adhesive sheet and the chip was heated at 175° C. for 2 hours by simulating the heat during the wire bonding thereby it was sealed (the sealing device MPC-06M TriAl Press made by APIC YAMADA CORPORATION) using the mold resin (KE-1100AS3 made by KYOCERA CHEMICAL CORPORATION) so that the sealed thickness became 400 μm. Subsequently, heated and pressurized thereof at 175° C., 6.9 MPa for 2 minutes, and then heated at 175° C. for 5 hours and cured the resin. Then, the circuit board being sealed was laminated to the dicing tape (Adwill D-510T made by Lintec Corporation), and it was diced into the size of 8 mm×8 mm using the dicing device (DFD651 made by DISCO Corporation), thereby the semiconductor package for the reliability evaluation was obtained.

### (Evaluation)

The obtained semiconductor package was left for 168 hours under the condition of 85° C. and the humidity of 60% RH, then after the moisture is absorbed, IR reflow (reflow furnace: WL-15-20DNX made by Sagami-Rikou Co. Ltd) of heating time of 1 minute in which the preheat of 130° C. (harsh condition) and the maximum temperature of 260° C. was carried out for three times; and the presence of the peeling at the connection part, the presence of the package crack was evaluated by a cross section observation using (VHX-100 made by KEYENCE CORPORATION) by grinding out the cross section using the scanning ultrasonic flow detection device (Hye-Focus made by Hitachi Construction Machinery Co., Ltd) and the cross section polishing machine (refine polisher HV made by Refinetec Corporation). When the peeling of 0.5 mm or longer was observed at the connection part of the semiconductor chip, it was determined as being peeled, and 27 packages were introduced into the test and the number of without a peel was counted.

### <The Adhesive Composition>

Each component constituting the adhesive composition are shown in the following.

(A-1) The acrylic polymer: copolymer comprising 95 parts by weight of methylacrylate and 5 parts by weight of 2-hydroxyethylacrylate (Mw: 500,000, Mw/Mn: 2.9, Tg: 9° C. made by TOYOCHEM CO., LTD.)
(A-2) The acrylic polymer: copolymer comprising 95 parts by weight of methylacrylate and 5 parts by weight of 2-hydroxyethylacrylate (Mw: 460,000, Mw/Mn: 3.2, Tg: 9° C. made by made by Nippon Synthetic Chemical Industry Co., Ltd.)
(B) The heat curable resin:
(B−1) Acryloyl group added cresol novolac epoxy resin (CNA-147 made by NIPPON KAYAKU Co., Ltd.)
(B-2) The heat curing agent: aralkylphenol resin (MILEX XLC-4 made by MITSUI CHEMICALS, INC.)
(C) The filler:
(C-1) methacryl group modified silica filler (average particle diameter 0.05 μm, made by Admatechs., 3-methacryloxypropyltrimethoxy silane treated product)
(C-2) methacryl group modified silica filler (average particle diameter 0.5 μm, SO-C2 made by Admatechs., 3-methacryloxypropyltrimethoxy silane treated product)
(C-3) vinyl group modified silica filler (average particle diameter 0.05 μm, made by Admatechs., vinyltrimethoxy silane treated product)
(C-4) trimethyl group modified silica filler (average particle diameter 0.07 μm, NSS-5N made by Tokuyama, trimethylsilyl treated product)
(F) silane coupling agent (MKC silicate MSEP2 made by MITSUI CHEMICALS, INC.)
(G) The crosslinking agent: aromatic polyvalent isocyanate (CORONATE L made by NIPPON POLYURETHANE INDUSTRY Co., Ltd.)
(J) non-modified silica filler (average particle diameter 0.4 μm, Sanshinoru SS-04 made by Tokuyama)

### Examples and Comparative Examples

### Adhesive Layer

The above mentioned components were blended in the amount (weight ratio) described in Tables 1 and 2, and obtained the adhesive composition. The methylethyl ketone solution (the solid portion concentration of 20 wt %) of the obtained adhesive composition, was coated and dried (drying condition: 100° C. for 1 minute in the oven) on the release treated face of the releasing film (SP-PET381031 made by Lintec Corporation) release treated with silicone so that the thickness after the drying is 20 μm; then it was laminated against the support (polyethylene film, the thickness of 100 μm, the surface tension of 33 mN/m); and the adhesive sheet was obtained by transferring the adhesive layer to the support. The semiconductor package was made using the obtained adhesive sheet, and the reliability was evaluated. Further, the adhesive sheet was obtained from the adhesive composition obtained by blending the amount described in Table 2 in a similar manner with above; in addition to the reliability thereof, shear strength of the adhesive layer after curing was measured. The results are shown in Tables 1 and 2. The PKG reliability in Tables 1 and 2 refers to the package reliability, and in the above mentioned evaluation, it is shown as the number without a peel off/27 (the number of the package introduced in the test).

TABLE 1

| | | Ex. 1 | Ex. 2 | Comp. Ex. 1 | Comp. Ex. 2 |
|---|---|---|---|---|---|
| Components | A-1 | 100 | 100 | 100 | |
| | A-2 | | | | 100 |
| | B-1 | 30 | 30 | 30 | 30 |
| | B-2 | 6 | 6 | 6 | 6 |
| | C-1 | 35 | | | 35 |
| | C-2 | | 35 | | |
| | F | 0.5 | 0.5 | 0.5 | 0.5 |
| | G | 1.5 | 1.5 | 1.5 | 1.5 |
| | J | | | 35 | |

| | | | | |
|---|---|---|---|---|
| PKG reliability | 27/27 | 16/27 | 0/27 | 5/27 |
| evaluation | | | | |

TABLE 2

| | | Ex. 3 | Ex. 4 | Comp. Ex. 3 | Comp. Ex. 4 |
|---|---|---|---|---|---|
| Components | A-1 | 100 | 100 | 100 | 100 |
| | B-1 | 30 | 30 | 30 | 30 |
| | B-2 | 30 | 6 | 6 | 6 |
| | C-1 | 35 | | | |
| | C-2 | | | 35 | |
| | C-3 | | 35 | | |
| | C-4 | | | | 35 |
| | F | 0.5 | 0.5 | 0.5 | 0.5 |
| | G | 1.5 | 1.5 | 1.5 | 1.5 |

| | | | | |
|---|---|---|---|---|
| Shear strength | 60 or | 60 or | less than | 60 or |
| measurement | more | more | 60 | more |
| (N/5 mm□) | | | | |
| PKG reliability | 27/27 | 27/27 | 16/27 | 0/27 |
| evaluation | | | | |

The adhesive compositions of Exs. 1 and 2, that are embodiments of the first invention, both improved package reliability of the semiconductor device, in relative to the adhesive compositions of Comp. Ex. 1 which do not include filler (C) having the reactive double bond group on the surface thereof, and of Comp. Ex. 2 which uses acrylic polymer having the weight average molecular weight of less than 500,000, that are comparative embodiments of the first invention. According to the first invention of the present invention, by using acrylic polymer (A) having the predetermined weight average molecular weight, heat curable resin (B) having the reactive double bond group, and filler (C) having the reactive double bond group on the surface thereof, filler (C) can be uniformly dispersed in the adhesive layer and the three dimensional network structure can be introduced in the adhesive layer. Thus, the semiconductor chip can be adhered to other semiconductor chip or the circuit board with a superior adhering strength, and a semiconductor device showing high package reliability can be obtained even under severe conditions. In addition, certain hardness can be provided to uncured or semi-cured adhesive layers, wire bonding can be stably performed even said wire bonding was carried out over a long period of time, when the process of carrying out simultaneous curing of the adhesive layer is applied for producing the multistacked package.

Shear strength of adhesive layers formed by the adhesive compositions of Exs. 3 and 4, which are embodiment of the second invention, were both 60N/5 mm□ or more. The adhesive compositions of Exs. 3 and 4 both improved reliability of the semiconductor device, in relative to the adhesive compositions of Comp. Ex. 3, which do not include filler (C) having the average particle diameter of 0.01 to 0.2 μm, and Comp. Ex. 4, which do not include filler (C) having the reactive double bond group on the surface thereof, that are comparative embodiments of the second invention.

According to the second invention of the present invention, by using acrylic polymer (A), heat curable resin (B) having the reactive double bond group, and filler (C) having the reactive double bond group on the surface thereof and having the predetermined average particle diameter, filler (C) can be uniformly dispersed in the adhesive layer and the three dimensional network structure can be introduced in the adhesive layer. Thus, the semiconductor chip can be adhered to other semiconductor chip or the circuit board with a superior adhering strength, and a semiconductor device showing high package reliability can be obtained even under a severe condition. In addition, certain hardness can be provided to uncured or semi-cured adhesive layers, wire bonding can be stably performed even said wire bonding was carried out over a long period of time, when the process of carrying out simultaneous curing of the adhesive layer is applied for producing the multistacked package.

1. An adhesive composition comprising:
an acrylic polymer (A),
a heat curable resin (B) having a reactive double bond group, and
a filler (C) having a reactive double bond group on a surface thereof,
wherein the acrylic polymer (A) has a weight average molecular weight of 500,000 or more, and the heat curable resin (B) comprising an epoxy resin and a heat curing agent, in which at least one of the epoxy resin and the heat curing agent has the reactive double bond group.

2. An adhesive composition comprising:
an acrylic polymer (A),
a heat curable resin (B) having a reactive double bond group, and
a filler (C) having a reactive double bond group on a surface thereof,
wherein the filler (C) has an average particle diameter of 0.01 to 0.2 μm, and the heat curable resin (B) comprising an epoxy resin and a heat curing agent, in which at least one of the epoxy resin and the heat curing agent has the reactive double bond group.

3. The adhesive composition as set forth in claim 1, wherein the filler (C) is silica having the reactive double bond group on a surface thereof.

4. The adhesive composition as set forth in claim 1, wherein a content ratio of the acrylic polymer (A) is 50 to 90 wt % with respect to a whole weight of the adhesive composition.

5. The adhesive composition as set forth in claim 1, wherein the acrylic polymer (A) has a hydroxyl group.

6. A single layer adhesive film comprising an adhesive composition as set forth in claim 1.

7. A single layer adhesive film comprising the adhesive composition as set forth in claim 2, wherein shear strength thereof after curing at 250° C. is 60N/5 mm² or more.

8. An adhesive sheet, wherein an adhesive layer, comprising the adhesive composition as set forth in claim 1, is formed on a support.

9. An adhesive sheet, wherein an adhesive layer, comprising the adhesive composition as set forth in claim 2, is formed on a support, and shear strength of the adhesive layer after curing at 250° C. is 60N/5 mm² or more.

10. The adhesive sheet as set forth in claim 8, wherein the support is a resin film.

11. The adhesive sheet as set forth in claim 8, wherein the support is a sticky sheet.

12. A production method of a semiconductor device comprising the steps of:
laminating the adhesive layer of the adhesive sheet as set forth in claim 8 on a semiconductor wafer,
dicing the semiconductor wafer and the adhesive layer, thereby obtaining a semiconductor chip,
releasing the semiconductor chip from the support while the adhesive layer is transferred to the semiconductor chip, and
adhering the semiconductor chip on a die pad or on other semiconductor chip via said adhesive layer.

13. A production method of a semiconductor device comprising the steps of:
separating a semiconductor wafer into individual semiconductor chips by forming a groove from the surface of the semiconductor wafer along an outline of a shape of the separating semiconductor chip,
laminating a protective sheet on the surface of the semiconductor wafer, and then performing a thinning treatment from the rear surface until reached to the groove,
laminating the adhesive layer of the adhesive sheet as set forth in claim 8 on the semiconductor chip,
releasing the semiconductor chip from the support while the adhesive layer is transferred to the semiconductor chip, and
adhering the semiconductor chip on a die pad or on other semiconductor chip via said adhesive layer.
